(19) United States
(12) Patent Application Publication
(10) Pub. No.: US 2002/0180475 A1
(43) Pub. Date: Dec. 5, 2002

(54) Manufacturing method and apparatus for probe carriers

(76) Inventors: Hidenori Watanabe, Kanagawa (JP); Tadashi Okamoto, Kanagawa (JP); Naoto Mihashi, Tokyo (JP)

Correspondence Address: FITZPATRICK CELLA HARPER & SCINTO, 30 ROCKEFELLER PLAZA, NEW YORK, NY, 10112, US

(21) Appl. No.: 10/105,363

(22) Filed: Mar. 26, 2002

(30) Foreign Application Priority Data
Mar. 28, 2001 (JP) 2001-094113

(51) Int. Cl. G01R 31/26

(52) U.S. Cl. 324/765

(57) ABSTRACT

Method of manufacture of probe carriers and an apparatus used for the method in which plural kinds of probes are arranged on a substrate by ejecting plural kinds of probe solutions containing probe materials specifically associable with target substances from a liquid ejecting device onto the substrate, wherein, when the probe solutions are ejected, the probe solutions ejected from the liquid ejection device are adhered on the base in elongated state following front ends of the solutions without splitting of the probe solutions on the way to the substrate. The method and the apparatus can provide probe carriers with areas and shapes of very high uniformity arranged on probe carrier bases.

This application claims the benefit of priority of Japanese Patent Application No. 2001-094113 filed on Mar. 28, 2001, the content of which is incorporated herein by reference.

### BACKGROUND OF THE INVENTION

1. Field of the Invention

The present invention relates to a manufacturing method for probe carriers on solid substrate and a manufacturing apparatus for probe carriers exclusively utilized for implementation of said manufacturing method. The present invention also relates to a liquid ejecting device for manufacturing probe carriers.

2. Description of the Related Art

In carrying out base sequence analysis of gene DNAs or simultaneous multitudinous high-reliability gene diagnosis, it is necessary to classify DNAs having desired base sequences by using plurality of probes. As a means for providing plurality of probes used for this classification works, DNA microchips are attracting attention. Further, in high-throughput screening of pharmaceuticals and development of pharmaceuticals by means of combinatorial chemistry, it is also necessary to carry out systematic screening of a large number (for example 96, 384 or 1536) of the solution of objective proteins and pharmaceuticals. For that purpose, there have been developed methods of arraying various pharmaceuticals, technology of for automated screening with such array, special-purpose apparatuses and softwares for controlling sets of screening operations and statistical treatment of the results.

Fundamentally, these parallel screening operations use so-called probe carriers (probe arrays) in which known probes, that serve as means of classification of substances to be evaluated, are arrayed. These operations detect whether the substances act or react on probe materials under the same conditions. Generally, it is previously determined which action or reaction to probe materials is utilized, so that the probe materials provided in a probe carrier are roughly classified into one kind of material, such as a group of probe material for DNAs with different base sequences. Namely, the substances utilized as a group of probe materials are, for example, DNAs, proteins, synthesized chemical substances (pharmaceuticals) or the like. In many cases, probe carriers consisting of a group of plural kinds of probes are used. However, some screening operation can use probe carriers in which many DNAs with an identical base sequence, many proteins with an identical amino acid sequence, and identical chemical substances are arranged on a lot of points as a probe, depending upon characteristics of the screening operations. These are mainly used for pharmaceutical screening.

In probe carriers consisting of a group of plural kinds of probes (particularly, a group of DNAs with different base sequences, a group of proteins with different amino acid sequences, or a group of different chemical substances), the plural kinds forming the group are often arranged according to a predetermined sequence order. Among them, DNA probe carriers are used when conducting analysis of base sequence of a gene DNA or when conducting simultaneous multitudinous high-reliability gene diagnoses.

As one of a method for arranging a group of plural kinds of probes on a substrate, plural kinds of probe solutions are ejected sequentially onto the substrate from a liquid ejection device in a desired timing to arrange them on the substrate. There have been disclosed some inventions concerning liquid ejection devices based on ink jet technologies which are generally used for printers.

For example, Japanese Patent Application Laid-open No. 11-187900(1999) discloses a method for arranging probes on solid phase by attaching liquids containing probe materials on the solid phase as droplets ejected from a thermal ink jet head. In this method, the probe materials are DNAs which are synthesized and purified in advance. In some cases, the lengths of bases are confirmed before attaching them on the solid phase.

Further, European Patent Publication No. EP 0703825B1 describes a method for solid phase synthesis of plural kinds of DNA each having a determined base sequence by supplying nucleotide monomers and activator, that are utilized for solid phase synthesis of DNA, from separate piezoelectric jet nozzles. This method conducts the solid phase synthesis of DNA on a substrate and supplies solutions of substances required for the synthesis by ink jet method at each elongation stage.

As introduced above, the ink jet technologies generally used for printers has been used as the conventional method for producing probe carriers.

However, some problems arose in preparation of probe carriers when printing (drawing) method adapted for printers applied as-is to arrangement of probes. This point will be described in detail below.

The test method using DNA probe carriers is generally carried out as follows. First, the DNA probe on the probe carrier base and the test substance are reacted. Here the test substance is bonded with a marker such as a fluorescent substance. The test substance reacts and associates with some of the probes on the probe carrier by hybridization. Washing of the probe carrier after hybridization leaves the fluorescent substance only where association occurred, and the amount of reaction is determined by measuring the amount of the fluorescent substance.

Area and shape of each probe on the probe carrier are very important in measuring the amount of fluorescent substance, since it is popular to measure optical intensity of fluorescent substances using a sensor. Even when ejection volume of probe solutions ejected from the liquid ejection device is the same amount, if the areas and the shapes of the probes arranged on the substrate are not uniform, density of the arranged probe materials becomes uneven, making it difficult to quantify the reaction in each probe.

Thus, uniformity of areas and shapes of the probe solutions which is ejected and adhered onto the substrate is very important in probe carrier formation. Area and shape of the ink ejected and adhered onto the paper are also important for the ink jet head of a printer. However, the allowable range of unevenness in printing is larger than that required in manufacturing probe carriers. Therefore, if the ink jet method of a printer is applied to manufacture of probe carriers as it is, manufacture of good probe carriers cannot be attained.

In conventional ordinary printers, the distance between the ink jet head and the object to be drawn (i.e. paper) is set to be 0.9 to 2.0 mm. This is because paper is a flexible material susceptible to deformation such as cockling and corrugation due to arrivals or permeation of inks, so that the head cannot get closer to the object of drawing than a certain extent.

When an ink of ordinary composition is flown between the above head and the paper at an ordinary ejection rate of ink droplet of 8 to 20 m/s, the ink droplet is split into plural ink droplets before it reaches the paper as shown in FIGS. 5A to 5E in order. Strictly speaking, FIGS. 5A to 5E show the behavior of liquid when a probe solution was ejected, but the behaviors of ejected liquids with similar physical properties are similar as described below.

In an ordinary printer, drawing is carried out by moving the head relative to the paper. Therefore, when the ink is split into plural ink droplets as described above, lags occur between the time for the first ink droplet to reach the paper and the times for the following ink droplets to reach the paper. Since the head is moving relative to the paper during the time lag, there occur gaps between the positions of arrivals of the first and the following ink droplets on the paper. the shape of the ink on the paper is good and close to perfect circle when the gaps of the positions of arrivals of the ink droplets on the paper are small. However, when the rate of movement of the head against the paper is relatively large, namely in the case of high speed printing, or when the speed difference of each ink droplets is large, the position of arrival of each split ink greatly differ and the shape of the ink on the paper is distorted. In the ordinary printed matters, distortion of the shape of ink on the paper is not the problem to a certain extent in many cases because it is not recognizable by human eyes. However, shape of probe is very significant in probe carriers as mentioned above.

The present invention solves the problem described above, and aims at providing a manufacturing method of probe carriers with very high uniformity of area and shape of each probe arranged on a probe carrier substrate in manufacturing of probe carriers using a liquid ejection device.

### SUMMARY OF THE INVENTION

The present inventors found that probes with very uniform probe areas and shapes can be arranged on a probe carrier substrate by controlling the shape of droplets of the probe solution ejected from the liquid ejection device when they adhere on the glass substrate to form probe carriers, as the result of eager research to solve the problem described above.

Thus, the present invention is characterized by arrivals of probe solutions ejected from the liquid ejection device on the carriers in elongated columnar state following the front edges of the solutions, without splitting of the ejected probe solution on the way to the substrate.

One of the embodiments of the present invention is a method of manufacturing probe carriers in which plural kinds of probes are arranged comprising the steps of: providing a substrate; and ejecting plural kinds of probe solutions, which contain probe material specifically associable with a target material, from a liquid ejection device onto the substrate, wherein, in ejecting the probe solutions, the probe solutions ejected from the liquid ejection device are adhered on the substrate in elongated state following front ends of the solutions without splitting of the probe solutions on the way to the substrate.

Another embodiment of the present invention is a manufacturing apparatus for probe carriers having a liquid ejection device for ejecting probe solutions which are specifically associable with target substances onto a substrate, the liquid ejection device being movable relatively to the substrate, wherein, in ejecting the probe solutions, the probe solutions ejected from the liquid ejection device are adhered on the substrate in elongated state following front ends of the solutions without splitting of the probe solutions on the way to the substrate

The above and other objects, effects, features and advantages of the present invention will become more apparent from the following description of embodiments thereof taken in conjunction with the accompanying drawings.

### BRIEF DESCRIPTION OF THE DRAWINGS

FIG. 1 is a schematic view showing an example of construction of a probe carrier manufacturing apparatus;

FIG. 2 is a schematic view showing an example of construction of a probe carrier;

FIG. 3 is a schematic cross-sectional view showing an example of construction of one of the liquid ejection units of a liquid ejection device;

FIG. 4 is a schematic cross-sectional view showing an example of construction of one of the liquid ejection units of a liquid ejection device;

FIGS. 5A to 5E are schematic views illustrating shape of ejected liquid;

FIGS. 6A to 6D are schematic views illustrating deterioration mechanism of shape of a probe; and

FIG. 7 is a graph showing the influence of ejection speed on the position of the front edge of a droplet before splitting.

### DETAILED DESCRIPTION OF PREFERRED EMBODIMENTS

The manufacturing method of probe carriers of the present invention will be explained below in more detail. While the examples shown here are best embodiments of the present invention, the present invention is not limited by the examples.

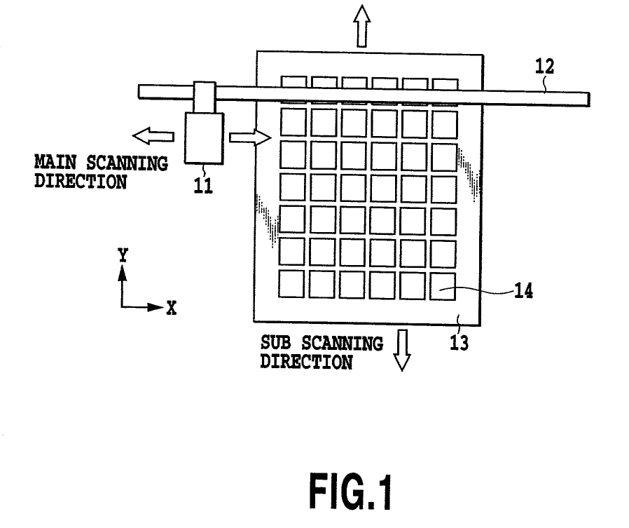

FIG. 1 shows a schematic view of the structure of a probe carrier manufacturing apparatus using a liquid ejection device. In FIG. 1, the reference numeral 11 denotes a liquid ejection device, the reference numeral 12 denotes a shaft for guiding the movement of the liquid ejection device substantially in the main scanning direction, the reference numeral 13 denotes a stage (substrate holding system) for holding the substrate of probe carriers, and the reference numeral 14 denotes a glass substrate that is the substrate for probe carriers.

The liquid ejection device 11 can be moved in the X direction in FIG. 1, and the stage 13 can be moved in the Y direction. Therefore, the liquid ejection device 11 can be two-dimensionally moved relative to the stage 13.

When the liquid ejection device 11 passes over the glass substrate 14 fixed to the stage 13, the probe solution is ejected from the liquid ejection device at desired timing to arrange the probe onto the glass substrate.

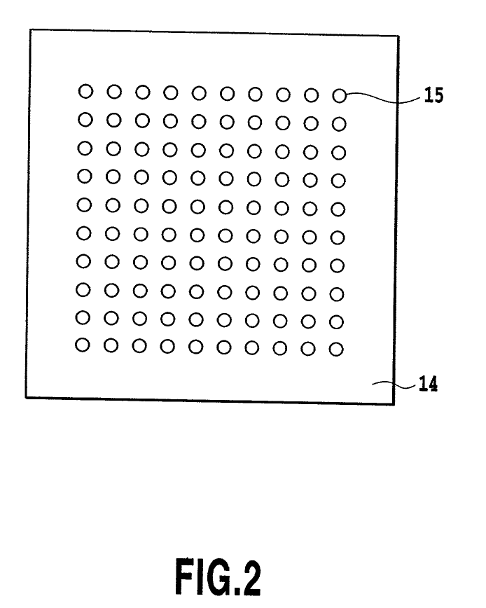

FIG. 2 shows a schematic view of a probe carrier. As shown in FIG. 2, in which probes 15 are arranged on the glass substrate 14.

When previously synthesized and purified probe materials (such as DNA) are arranged onto the substrate, the liquid ejection device 11 preferably has a structure provided with nozzles that can eject the same number of probe solutions as the number of probes arranged onto the glass substrate.

Preferably, the density of arrangement of the nozzles of the liquid ejection device equals to the density of arrangement of the probes in the probe carriers to be prepared, since the probe carrier can be prepared by one scanning of the liquid ejection device.

Further, while FIG. 1 shows the structure of a probe carrier manufacturing apparatus for arranging probes on plurality of fixed glass substrates 14, probes can also be arranged on a large glass substrate which is then cut to give plurality of probe carriers.

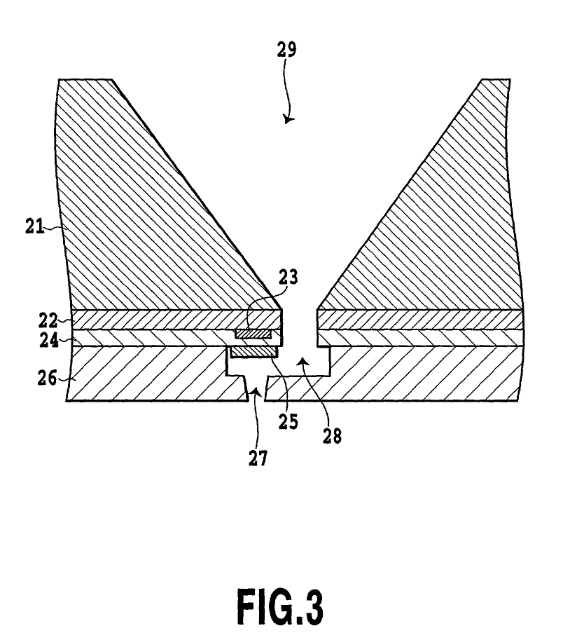

FIG. 3 is a schematic view showing one of the liquid ejection units of a liquid ejection device. The liquid ejection method includes the bubblejet method that ejects liquid by means of thermal energy generated by a heater, and the piezoelectric jet method that ejects liquid by means of deformation of piezoelectric elements caused by applying voltage to the elements. FIG. 3 shows the structure of a liquid ejection device of the bubblejet method.

In FIG. 3, the reference numeral 21 denotes a silicon base, the reference numeral 22 denotes an insulating layer, the reference numeral 23 denotes a heater consisting of TaN, TaSi, TaAl, etc., the reference numeral 24 denotes a passivation layer, the reference numeral 25 denotes a cavitation-resistant layer, the reference numeral 26 denotes the nozzle material, the reference numeral 27 denotes a nozzle, the reference numeral 28 denotes the flow path, and the reference numeral 29 denotes the feed opening.

The heater 23 is connected at both ends to wiring (not shown) of aluminum, etc., through which desired voltage pulses are applied at both ends of the heater 23.

The insulating layer 24 can be either thermal-oxide layer formed by thermal oxidation of the silicon substrate, or oxide or nitride layer formed by CVD.

The nozzle material 26 that form nozzles 27 and the flow paths 28 can be formed either by sticking nozzle material that the nozzles and a flow paths are already formed to the semiconductor substrate, or by using a semiconductor process based upon photolithography technology.

The feed opening 29 is formed by anisotropic etching of silicon using an aqueous solution of tetramethylammonium hydroxide (TMAH). In the case of a silicon base having (100) plane on the surface, an aperture is made at a slant against the surface of the base, whose angle is 54.7° as shown in FIG. 3. The feed opening 29 feeds the probe solution from the rear surface of the substrate to the front surface of the substrate, and also functions as a liquid reservoir for holding liquid.

When only a small number of probe carriers are manufactured and amount of probe solution ejected onto a probe is small, there are cases where the amount of probe solution existing in the feed opening is sufficient for manufacture of a series of the probe carriers. When the probe solutions should be ejected in larger amount, secondary reservoirs (not shown) connected to the feed openings 29 are provided.

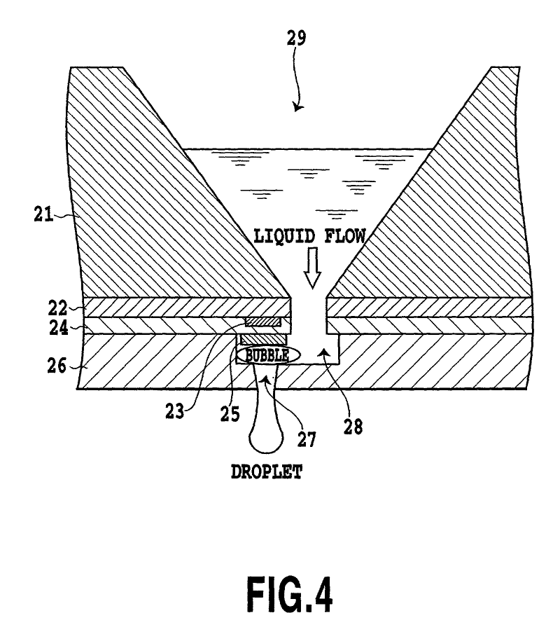

The probe solution is lead from the feed opening 29 on the rear surface of the substrate through the flow path 28 to the nozzle 27 on the front surface of the substrate as shown in FIG. 4. When desired voltage pulse is applied at both ends of the heater 53, the probe solution near the heater is superheated to cause film-boiling, and the liquid is ejected as shown in FIG. 4.

In order to eject probe solutions stably, it is essential to give rise to film-boiling stably. In order to give rise to film-boiling stably, it is desirable to apply voltage pulse of 0.1 to 5 μs to the heater.

The amount of probe solution ejected at one time from a nozzle is appropriately selected, taking account of various factors such as viscosity of probe solutions, affinity of probe solutions with the solid substrate, and reactivity of probe materials with the solid substrate, and according to the shape and dot size of the probe formed. Aqueous solvent is generally used for the probe solutions. In the method of the present invention, the volume of droplets of probe solutions ejected from each nozzle of the liquid ejection device is generally selected within the range of 0.1 pl to 100 pl. The nozzle diameter, etc., are preferably designed to fit the above volume.

The area occupied by array units (dots) on which the probe solution is applied is generally 0.01μm² to 40000μm², determined by the size of the probe carrier itself and the density of arrangement of the probes.

In the present invention, the probes fixed to the substrate are specifically associable with specific target substances. In the embodiment of the present invention, the target substances are nucleic acids, and the probes are single-strand nucleic acids which have complemental base sequence to the whole or part of the target nucleic acid, so that the probes can specifically hybridize with the base sequence of the target nucleic acids. Further, the probes include oligonucleotides, polynucleotides, and other polymers that can recognize specific targets. The term “probes” means both of individual molecules having probe functions such as polynucleotide molecules and a mass of molecules having same probe functions fixed on the surface at separate positions such as polynucleotides with same sequences, often including molecules so-called ligands. Further, probes and targets are often exchangeably used, and the probes are substances either associable with targets as parts of ligand-antiligand (sometimes called receptor) pairs or changeable to substances that associate thereto. The probes and targets in the present invention can include bases found in nature and similar substances.

Examples of probes held on the substrate include oligonucleotides having base sequences hybridizable to target nucleic acids and having a bonding part to the substrate via linkers, the probe having structures connected to the surface of the substrate in the bonding part. The probe is preferably single-strand nucleic acid which has base sequence complemental to all or part of target nucleic acid and can hybridize specifically with the target nucleic acid. Further, in such a configuration the positions of the bonding part to the substrate in the oligonucleotide molecules are not limited as far as desired hybridization reaction is not damaged.

The probes adopted in the probe carriers manufactured by the method of the present invention are appropriately selected in their purpose of use. In order to implement the method of the present invention appropriately, the probes are preferably DNAs, RNAs, cDNAs (complementary DNAs), PNAs, oligonucleotides, polynucleotides, other nucleic acids, oligopeptides, polypeptides, proteins, enzymes, substrates for enzymes, antibodies, epitopes for antibodies, antigens, hormones, hormone receptors, ligands, ligand receptors, oligosaccharides, or polysaccharides, of which two or more can be used in combination if necessary.

In the present invention, plural kinds of these probes fixed on the separate regions (such as dot-shaped spots) of the surface of the substrate (including internal surfaces of hollow or ring shaped carriers) are called “probe carrier”, and those arranged at determined intervals are called “probe array”.

It is desirable that probe materials have structures bondable to the solid phase substrate, and are bonded to the solid phase substrate utilizing such bondable structures after ejection and application of probe solutions. The structures bondable to the solid phase substrate can be formed by introducing organic functional groups such as amino, mercapto, carboxyl, hydroxyl, acid halide (—COX), halogen, aziridine, maleimide, succinimide, isothiocyanate, sulfonyl chloride (—SO₂Cl), aldehyde (—CHO), hydrazine, and iodoaceatamide groups into the probe material molecules in advance. In that case, it is also necessary to introduce structures (organic functional groups) onto the surface of the substrate in advance, that form covalent bonds by reacting with the various functional groups described above. For example, when the probe material has amino groups, succinimide ester, isothiocyanate, sulfonyl chloride, or aldehyde can be introduced on the surface of the substrate. When the probe material has mercapto (thiol) groups, maleimide can be introduced on the surface of the substrate. When a glass substrate is used as the substrate, desired functional groups can be introduced on the surface thereof using a silane coupling agent having desired functional groups as well as a cross linker having desired functional groups.

Next the structure characteristic of the present invention will be explained.

The thermal jet type liquid ejection device explained using FIG. 3 can vary ejection volume and ejection speed by varying size of the heater, structure of flow path such as height and width, shape of the nozzles such as diameter and height, and shape of applied voltage pulses.

The shape of probes on the probe carrier was observed using a probe solution containing DNA oligomer dissolved at a concentration of 8μM (about 0.005% by weight) in a solution of the composition shown in Table 1 as a probe material, and varying distance between the liquid ejection device and the substrate. Ejection of the probe solution was carried out using a head with the ejection volume of 15 pl and ejection speed of 15 m/s. The shape of probes was observed visually using a microscope.

TABLE 1

| ingredient | content (% by weight) |
|---|---|
| glycerin | 7.5 |
| thiodiglycol | 7.5 |
| urea | 7.5 |
| acetylene alcohol | 1.0 |
| (trademark: acetylenol, available | |
| from Kawaken Chemical Co.) | |
| water | 76.5 |

Physical properties of the solution with the composition shown above are shown in Table 2. The physical properties of the solution are almost the same as those of inks generally used for printing. Viscosity was measured at room temperature using a cone-plate type rotational viscometer (RE-80-L from Toki Sangyo), and surface tension was measured at room temperature using a static surface tension meter (Wilhelmy method; CBVP-A3 from Kyowa Interface Science Co. Ltd.).

TABLE 2

| Physical properties | measured value |
|---|---|
| density (ρ) | 1.05 g/cm³ = 1.0 × 10³ kg/m³ |
| viscosity (η) | 1.90 cP = 1.90 × 10⁻³ Pa · s |
| surface tension (σ) | 30.0 dyne/cm = 3.00 × 10⁻² N/m |

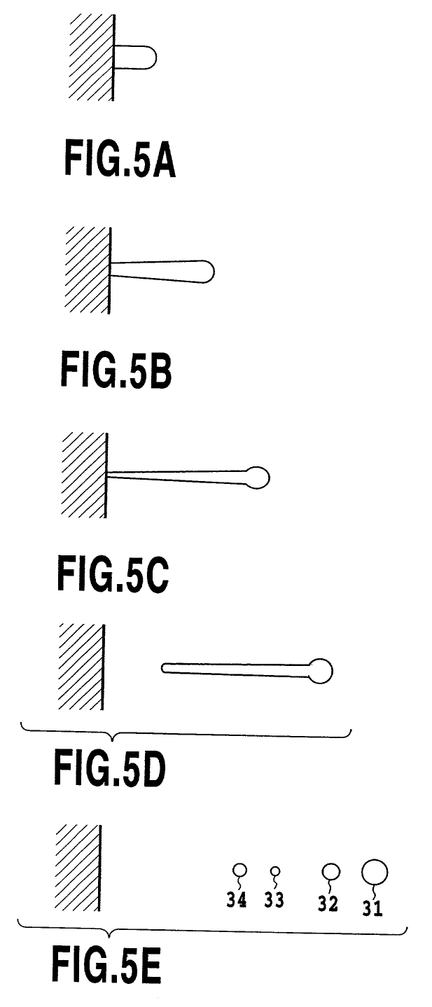

When a probe solution with such physical properties is ejected from a liquid ejection device with ejection volume of 15 pl and ejection speed of 15 m/s, the liquid droplets are split into plural droplets as mentioned above. With the liquid ejection device used this time, the droplets were mostly split into four as shown in FIG. 5E. The ejected probe solution is columnar at first, then forms a constriction (columnar with elongated solution following the ejected front end) in the vicinity of the front end, and splits into plural droplets as time passes further.

The number of droplets that an ejected droplet splits into and the time until it splits into plural droplets after ejection depend on the shapes of the nozzle and flow path, ejection speed, and ejection volume of the liquid ejection device and physical properties of the droplets such as viscosity and surface tension. However, a series of change in shape of ejected liquid takes the same tendency irrespective of the ejection condition, that is:

(1) columnar (the state shown in FIGS. 5A and 5B);

(2) columnar state where the solution is elongated following the constricted front end (the state shown in FIG. 5C);

(3) columnar state where tail end is separated from the liquid ejection device in the state shown in FIG. 5C (the state shown in FIG. 5D); and

(4) the state of the solution being split into plural droplets (the state shown in FIG. 5E).

The state of FIGS. 5C and 5D is “the state of solution elongated following the front end without splitting of the probe solution on the way to the substrate” of the present invention. By the phrase “without splitting of the probe solution on the way to the substrate” is meant herein that the probe solution is not split into plural droplet on the way to the substrate, as shown in FIG. 5E.

Among the split droplets the first droplet 31 has the biggest volume and is generally referred to as the primary droplet 31. The split droplets 32 through 34 except the primary droplet 31 are referred to as “satellites”. Speed of the primary droplets and the time until the ejected solution splits into plural droplets do not vary much in any cases. However, the number of satellites 32 through 34 and their speed relatively vary depending upon individual nozzles and ejections.

Table 3 shows the influence of the distance between the liquid ejection device and the base on the shape of the probe on the base. The shapes of probes were examined in cases of scanning speeds of the liquid ejection device, namely relative speed of the liquid ejection device and the base, of 70 cm/s and 35 cm/s.

TABLE 3

| | |
|---|---|
| distance between the liquid | |
| ejection device and the | scanning speed |

| substrate | 35 cm/s | 70 cm/s |
|---|---|---|
| 0.2 mm | A | A |
| 0.3 mm | A | A |
| 0.5 mm | A | B |
| 1.0 mm | B | C |
| 1.5 mm | C | C |

Table 3 shows that the shape of probe: the symbol “A” denotes that the shape is ideal and close to a perfect circle, the symbol “B” denotes that the shape is somewhat deformed from a perfect circle although there are no practical problems, and the symbol “C” denotes that the shape cannot be called a circle.

When the distance between the liquid ejection device and the substrate was less than 0.3 mm, obtained probe shapes were good and close to perfect circles at any scanning speed. At the scanning speed of 70 cm/s, the shape of probe began to get deformed from a perfect circle at distance between the liquid ejection device and the substrate of 0.5 mm although there are no practical problems, and could not be called a circle when it was 1.0 mm or more. At the scanning speed of 35 cm/s, the shape of probe began to get deformed from a perfect circle at distance between the liquid ejection device and the substrate of 1.0 mm although there are no practical problems, and could not be called a circle when it was 1.5 mm.

The phenomenon can be explained as follows. Although the probe solution was actually split into four droplets, only the primary droplet 31 and the last satellite droplet 34 were noticed and explained to make the point clear.

When ejected probe solution was not substantially split and in an elongated columnar shape following the front end, as in FIG. 5C, the front end of the primary droplet was about 0.3 mm apart from the surface of the liquid ejection device. Then local constriction occur in the column and finally the column splits into plural droplets as shown in FIG. 5E. At the time of splitting, the front end of the primary droplet 31 was about 0.38 mm apart from the surface of the liquid ejection device and the speed of the primary droplet was 15 m/s. In the other hand, the front end of the last droplet 34 was about 0.20 mm apart from the surface of the liquid ejection device and the speed of the primary droplet was 10 m/s.

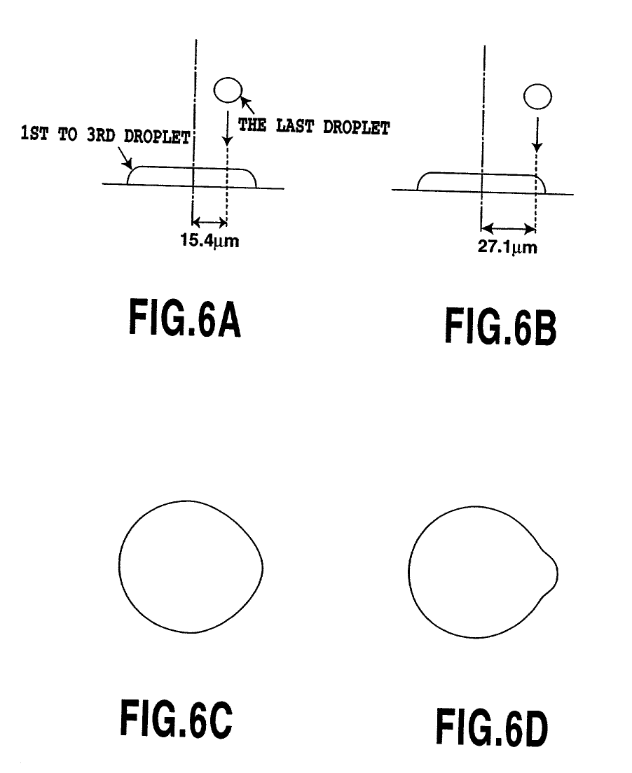

In the case that the distance between the liquid ejection device and the substrate is 0.5 mm, the primary droplet 31 moves the distance of 0.12 mm at 15 m/s after its formation, while the last droplet 34 moves the distance of 0.3 mm at 10 m/s after the separation (splitting). Therefore, it takes 22 μs after the primary droplet 31 reaches the substrate for the last droplet 34 to reach the substrate. Where the scanning speed of the liquid ejection device is 70 cm/s, during the time of 22 μs the positions of arrivals of the primary droplet 31 and the last droplet 34 on the substrate become 15.4 μm apart.

Where the ejection volume is 15 pl, the probe formed on the substrate becomes a circle with diameter of about 65 μm. If the positions of arrivals of the primary droplet 31 become apart from that of the satellite droplet 34, the shape of finally obtained probe deviates from a circle. The behavior is shown in FIGS. 6A to 6D. FIG. 6A is a schematic cross-sectional view of shape of a probe in a plane perpendicular to the substrate surface when the distance between the liquid ejection device and the substrate is 0.5 mm, ejection volume is 15 pl , and scanning speed is 70 cm/s, and FIG. 6C is a schematic top view of shape of a probe formed under the same condition.

In the case of larger distance of 1.0 mm between the liquid ejection device and the substrate, the primary droplet 31 moves the distance of 0.62 mm at 15 m/s after formation, while the last droplet 34 moves the distance of 0.8 mm at 10 m/s after separation. Therefore, it takes 38.7 μs after the primary droplet 31 reaches the substrate until the last droplet 34 reaches the substrate. When the scanning speed of the liquid ejection device is 70 cm/s, during the time of 38.7 μs, the positions of arrivals of the primary droplet 31 and the last droplet 34 on the substrate become 27.1 μm apart.

This feature is schematically shown in FIGS. 6B and 6D. FIG. 6B is a schematic cross-sectional view of shape of a probe in a plane perpendicular to the substrate surface when the distance between the liquid ejection device and the substrate is 1.0 mm, ejection volume is 15 pl, and scanning speed is 70 cm/s, and FIG. 6D is a schematic top view of shape of a probe formed under the same condition. As shown in FIGS. 6A to 6D, large misalignment of the positions of arrivals of the primary and the last droplets greatly deforms the shape of the obtained probe.

Similarly, shape of a probe is further deformed when the distance between the liquid ejection device and the substrate is even longer. It can be understood in the same way of consideration that shape of a probe is further deformed also when difference of speed of the primary and the last droplets is larger.

When scanning speed of the liquid ejection device is 35 cm/s, misalignment of the positions of arrivals between the primary droplet 31 and the satellite droplets 32 to 34 is smaller than when it is 70 cm/s as described above. Thus, low scanning speed of the liquid ejection device tends to make the shape of a probe better circle. However, lower scanning speed reduces the throughput of probe carrier manufacture.

As described above, when the ejected solution splits into plural droplets, differences in the position and in the speed of droplets when they are split can deteriorate the shape of a probe. Therefore, in order to realize good shape of a probe, it is desirable to adhere the ejected solution on the substrate without splitting of the ejected solution into plural droplets, namely when the solution is in a columnar state elongated following the front end thereof without substantially splitting the probe solution (the shape shown in FIGS. 5C and 5D).

In the case of manufacture of probe carriers, the object of drawing is a glass substrate having stable shape and high flatness, so that the distance between the liquid ejection device and the substrate can be set small. Further, when the distance between the liquid ejection device and the substrate is set small, positional precision of probe arrangement can also be improved.

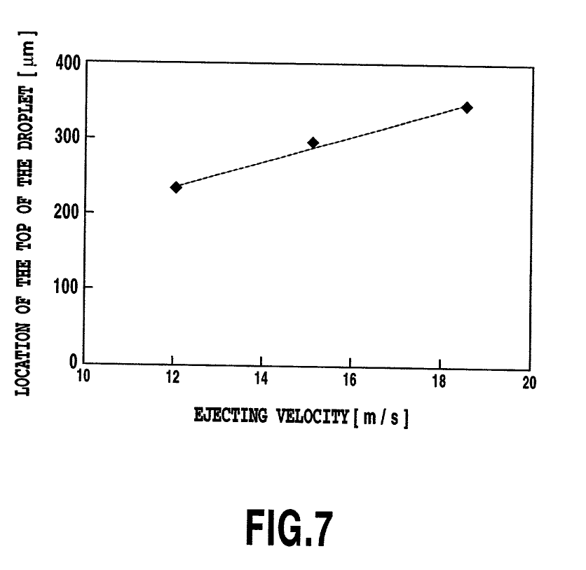

FIG. 7 shows ejection speed dependence of the position of front end of ejected solution when the solution is in the form of an elongated column following the front end (the shape shown in FIGS. 5C and 5D). The position of the front end of ejected solution is represented as the distance from the surface of the liquid ejection device. As shown in FIG. 7, the position of the front end of ejected solution when the solution is in the form of an elongated column following the front end, depends on the ejection speed, and becomes larger as the ejection speed becomes faster.

From the above description, it is understood that probe carriers with ideal probe shape close to perfect circle can be manufactured by adjusting the distance between the liquid ejection device and the substrate and ejection speed so that ejected solution is controlled to adhere on the substrate in the form of an elongated column following the front end.

While the case of ejection rate of 15 pl has been explained so far, ejected probe solution can be adhered on the substrate in the form of an elongated column following the front end and probe carriers with ideal probe shape close to perfect circle can be manufactured at any ejection volume, by adjusting the distance between the liquid ejection device and the substrate and ejection speed in the same way of consideration.

Further, it is obvious that the same advantages are achieved when using piezoelectric jet type liquid ejecting device, even though the foregoing description explains the case where bubblejet type liquid ejecting device are used as an example.

A typical structure and operational principle thereof is disclosed in U.S. Pat. Nos. 4,723,129 and 4,740,796, and it is preferable to use this basic principle to implement such a system. Although this system can be applied either to on-demand type or continuous type liquid ejection systems, it is particularly suitable for the on-demand type apparatus. This is because the on-demand type apparatus has electrothermal transducers, each disposed on a sheet or liquid passage that retains liquid (ink), and operates as follows: first, one or more drive signals are applied to the electrothermal transducers to cause thermal energy corresponding to manufacturing information; second, the thermal energy induces sudden temperature rise that exceeds the nucleate boiling so as to cause the film boiling on heating portions of the liquid ejecting device; and third, bubbles are grown in the liquid (ink) corresponding to the drive signals. By using the growth and collapse of the bubbles, the ink is expelled from at least one of the ink ejection orifices of the head to form one or more ink drops. The drive signal in the form of a pulse is preferable because the growth and collapse of the bubbles can be achieved instantaneously and suitably by this form of drive signal. As a drive signal in the form of a pulse, those described in U.S. Pat. Nos. 4,463,359 and 4,345,262 are preferable. In addition, it is preferable that the rate of temperature rise of the heating portions described in U.S. Pat. No. 4,313,124 be adopted to achieve better probe formation.

U.S. Pat. Nos. 4,558,333 and 4,459,600 disclose the following structure of a liquid ejecting device, which is incorporated to the present invention: this structure includes heating portions disposed on bent portions in addition to a combination of the ejection orifices, liquid passages (linear passages or right-angled passages) and the electrothermal transducers disclosed in the above patents. Moreover, the present invention can be applied to structures disclosed in Japanese Patent Application Laid-open Nos. 59-123670(1984) and 59-138461(1984) in order to achieve similar effects. The former discloses a structure in which a slit common to all the electrothermal transducers is used as ejection orifices of the electrothermal transducers, and the latter discloses a structure in which openings for absorbing pressure waves caused by thermal energy are formed corresponding to the ejection orifices. Thus, irrespective of the type of the liquid ejecting device, the present invention can achieve manufacture of probe carriers positively and effectively.

The present invention can be also applied to a so-called full-line type liquid ejecting device whose length equals the maximum length across a stage. Such a liquid ejecting device may consists of a plurality of liquid ejecting devices combined together, or one integrally arranged liquid ejecting device.

In addition, the present invention can be applied to various serial type liquid ejecting devices: a liquid ejecting device fixed to the main assembly of a manufacturing apparatus; a conveniently replaceable chip type liquid ejecting device which is electrically connected to the main assembly of a manufacturing apparatus, and is supplied with ink therefrom when the device is loaded on the main assembly.

It is further preferable to add a recovery system, or a preliminary auxiliary system for a liquid ejecting device as a constituent of the manufacturing apparatus because they serve to make the effect of the present invention more reliable. Examples of the recovery system are a capping means and a cleaning means for the liquid ejecting device, and a pressure or suction means for the liquid ejecting device. Examples of the preliminary auxiliary system are a preliminary heating means utilizing electrothermal transducers or a combination of other heater elements and the electrothermal transducers, and means for carrying out preliminary ejection of liquid independently of the ejection for forming a probe. These systems are effective for reliable formation of a probe carrier.

The present invention has been described in detail with respect to preferred embodiments, and it will now be apparent from the foregoing to those skilled in the art that changes and modifications may be made without departing from the invention in its broader aspect, and it is the intention, therefore, in the apparent claims to cover all such changes and modifications as fall within the true spirit of the invention.

What is claimed is:

1. A method of manufacturing probe carriers in which plural kinds of probes are arranged comprising the steps of:
providing a substrate; and
ejecting plural kinds of probe solutions, which contain probe material specifically associable with a target material, from a liquid ejection device onto said substrate,
wherein, in ejecting said probe solutions, said probe solutions ejected from the liquid ejection device are adhered on the substrate in elongated state following front ends of said solutions without splitting of said probe solutions on the way to said substrate.

2. A method of manufacturing probe carriers as claimed in claim 1, wherein the probe solutions ejected from said liquid ejection device are adhered on said substrate before said solutions are separated from said liquid ejection device.

3. A method of manufacturing probe carriers as claimed in claim 1, wherein ejection operation is performed on the state that the distance between said liquid ejection device and said substrate is a given value, in order that said probe solutions ejected from said liquid ejection device are adhered on said substrate in the elongated state following front ends of said solutions.

4. A method of manufacturing probe carriers as claimed in claim 3, wherein ejection speed of said probe solutions is ejected in a given ejection speed, in order that said solutions ejected from said liquid ejection device are adhered on said substrate in the elongated state following front ends of said solutions.

5. A method of manufacturing probe carriers as claimed in claim 1, wherein said liquid ejection device comprises a thermal energy generating element that generates thermal energy applied to probe solutions in order to eject probe solutions.

6. A method for manufacturing probe carriers as claimed in claim 1, wherein said target substance is a nucleic acid, and said probe is a single-strand nucleic acid which has base sequence complemental to all or part of said nucleic acid and hybridize specifically to a base sequence of said nucleic acid.

7. A manufacturing apparatus for probe carriers having a liquid ejection device for ejecting probe solutions which are specifically associable with target substances onto a substrate, said liquid ejection device being movable relatively to said substrate,
wherein, in ejecting said probe solutions, said probe solutions ejected from said liquid ejection device are adhered on the substrate in elongated state following front ends of said solutions without splitting of said probe solutions on the way to said substrate.

8. A manufacturing apparatus for probe carriers as claimed in claim 7, wherein said probe solutions ejected from said liquid ejection device are adhered on said substrate in elongated state following front ends of said solutions without splitting of said probe solutions on the way to said substrate.

9. A manufacturing apparatus for probe carriers as claimed in claim 7, wherein said liquid ejection device comprises a thermal energy generating element that generates thermal energy applied to probe solutions in order to eject probe solutions.
